(19) United States
(12) Patent Application Publication
(10) Pub. No.: US 2025/0300134 A1
(43) Pub. Date: Sep. 25, 2025

(54) PACKAGE SUBSTRATE HAVING STACKED ELECTRONIC COMPONENT STRUCTURE DISPOSED IN A CAVITY OF A CORE

(71) Applicant: QUALCOMM Incorporated, San Diego, CA (US)

(72) Inventors: Yujen CHEN, Taichung (TW); Aniket PATIL, San Diego, CA (US); Yangyang SUN, San Diego, CA (US)

(21) Appl. No.: 18/609,681

(22) Filed: Mar. 19, 2024

(51) Int. Cl. H01L 25/065; H01L 23/00; H01L 23/48; H01L 23/498

(52) U.S. Cl. CPC H01L 25/0657; H01L 23/481; H01L 23/49822; H01L 24/16; H01L 24/32; H01L 2224/16225; H01L 2224/32225; H01L 2225/06541; H01L 2924/19041; H01L 2924/19042

(57) ABSTRACT

In an aspect, a substrate includes a core having a cavity; a first set of one or more metallization layers disposed at an upper portion of the core; and a stacked electronic component structure disposed in the cavity, wherein the stacked electronic component structure comprises a first electronic component including an upper surface having a second set of one or more metallization layers and a first set of via structures electrically coupling the first electronic component with the first set of one or more metallization layers, and a second electronic component over the first electronic, the second electronic component including an upper surface having a third set of one or more metallization layers electrically coupling the second electronic component with the first set of one or more first metallization layers.

### FIELD OF DISCLOSURE

The present disclosure generally relates to a package substrate, and more particularly, to a package substrate having a stacked electronic component disposed in a cavity of a core substrate of the package substrate.

### BACKGROUND

Integrated circuit (IC) technology has achieved great strides in advancing computing power through miniaturization of electrical components. An IC may be implemented in the form of an IC chip that has a set of circuits integrated thereon. In some implementations, one or more IC chips can be physically carried and protected by an IC package, where various power and signal nodes of the one or more IC chips can be electrically coupled to respective conductive terminals of the IC package via electrical paths formed in a package substrate of the IC package. Various packaging technologies can be found in many electronic devices, including processors, servers, radio frequency (RF) integrated circuits, etc. Advanced packaging and processing techniques can be used to implement complex devices, such as multi-electronic component devices and system on-a-chip (SOC) devices, which may include multiple function blocks, with each function block designed to perform a specific function, such as, for example, a microprocessor function, a graphics processing unit (GPU) function, a communications function (e.g., WiFi, Bluetooth, and other communications), and the like.

In some implementations, embedded electronic components, such as deep trench capacitors, have been incorporated in IC packaging for performance improvement and package size reduction. One factor driving the use of such embedded electronic components is the desire for obtaining small form factor products with equivalent or better electrical performance than their larger electronic component counterparts.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a substrate includes a core having a cavity; a first set of one or more metallization layers disposed at an upper portion of the core; and a stacked electronic component structure disposed in the cavity, wherein the stacked electronic component structure comprises a first electronic component including an upper surface having a second set of one or more metallization layers and a first set of via structures electrically coupling the first electronic component with the first set of one or more metallization layers, and a second electronic component over the first electronic, the second electronic component including an upper surface having a third set of one or more metallization layers electrically coupling the second electronic component with the first set of one or more first metallization layers.

In an aspect, an electronic device includes a substrate comprising a core substrate including a core having a cavity; a first set of one or more metallization layers disposed at an upper portion of the cavity; and a stacked electronic component structure disposed in the cavity, wherein the stacked electronic component structure comprises a first electronic component including an upper surface having a second set of one or more metallization layers and a first set of vias electrically coupling the first electronic component with the first set of one or more metallization layers, and a second electronic component over the first electronic component, the second electronic component including an upper surface having a third set of one or more metallization layers electrically coupling the second electronic component with the first set of one or more metallization layers.

In an aspect, a method of forming a substrate includes forming a stacked electronic component structure comprising a first electronic component including an upper surface having a first set of one or more metallization layers and a first set of vias electrically coupling the first electronic component with a first set of one or more pads disposed at an upper surface of the stacked electronic component structure, and a second electronic component over the first electronic component, the second electronic component including an upper surface having a second set of one or more metallization layers electrically coupling the second electronic component with a second set of one or more pads disposed at the upper surface of the stacked electronic component structure; and positioning the stacked electronic component structure in a cavity of a core substrate.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings, which are presented solely for illustration and not limitation of the disclosure.

FIG. 1 is a cross-sectional view of a first example substrate with an embedded electronic component, according to aspects of the disclosure.

FIG. 2 is a cross-sectional view of an example substrate having stacked electronic components disposed in the cavity of a core, according to aspects of the disclosure.

FIG. 3 is a cross-sectional view of an example substrate having stacked electronic components disposed in the cavity of a core, according to aspects of the disclosure.

FIG. 4 through FIG. 7 illustrate various stacked electronic component structures, according to aspects of the disclosure.

FIG. 8A through FIG. 8D depict exemplary operations that may be used to fabricate a stacked electronic component, according to aspects of the disclosure.

FIG. 9A through FIG. 9D depict exemplary operations that may be used to fabricate a stacked electronic component, according to aspects of the disclosure.

FIG. 10 is a flowchart showing an example method for fabricating a substrate, according to aspects of the disclosure.

FIG. 11 illustrates a profile view of a package that includes a surface mount substrate, an integrated device, and a substrate structure having a stacked electronic component structure disposed in a cavity of a core, according to aspects the disclosure.

FIG. 12 illustrates an example method for providing or fabricating a package that includes an integrated device comprising a substrate having an electronic component on a core, according to aspects of the disclosure.

FIG. 13 illustrates various electronic devices that may be integrated with any of the aforementioned devices, according to aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

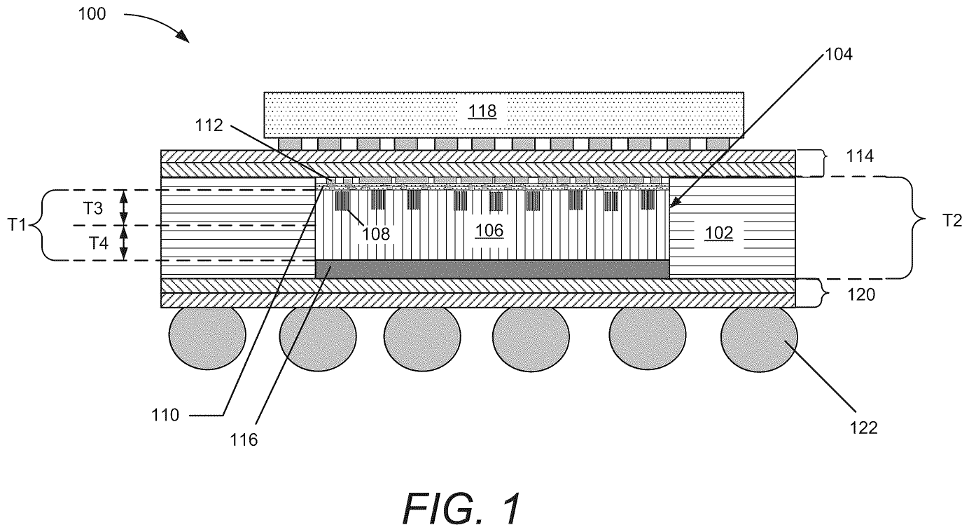

FIG. 1 is a cross-sectional view of a first example substrate 100 with an embedded electronic component, according to aspects of the disclosure. In this example, the substrate 100 includes a core 102 having a cavity 104 that extends entirely through the core 102. An electronic component 106 is disposed within the cavity 104. In this example, the electronic component 106 comprises a plurality of deep trench capacitors (DTC) 108. The electronic component 106 has one or more metallization layers 110 disposed at an upper surface of the electronic component 106 with an uppermost portion having metal terminals 112 that provide an electrical connection between the electronic component 106 and one or more metallization layers 114. Since the thickness T1 of the electronic component 106 is less than the depth T2 of the cavity 104, the lower portion of the cavity 104 includes a material (e.g., a dielectric resin) forming a support structure 116. The support structure 116 raises the electronic component 106 to a position within the cavity 104 in which the metal terminals 112 may be connected to the metallization of the metallization layers 114. In this example, the metallization layers are patterned metallization layers but are not shown with a particular arrangement of pads and via structures since the structures of such elements are design defect it and In accordance with various aspects of the disclosure, the electronic component 106 may alternatively be one or more of an active electronic component, a passive electronic component (e.g., a deep trench capacitor (DTC)), a die, etc.

In accordance with various aspects of the disclosure, the substrates described herein (e.g., substrate 100) that include a core and an embedded electronic component are directed to package substrates. A package substrate is the part of an integrated circuit package that gives the board its mechanical strength and allows it to connect with external devices. Such package substrates are to be distinguished from other substrates, such as the substrates that may be included in the embedded electronic component itself, dies including substrates (e.g., silicon substrates or other similar electronic devices), etc. In FIG. 1, an external device is illustrated as an integrated circuit package 118 at an upper portion of the substrate 100. The substrate 100 is further configured for electrical connection to another device or substrate through one or more patterned metallization layers 120 and corresponding solder joints 122.

Although the structure of the substrate 100 shown in FIG. 1 has been suitable for use in many high-performance applications (e.g., compute and automotive applications), current trends are directed to applications requiring substrates having higher electronic component densities. Certain aspects of the disclosure are implemented with a recognition that the space within the cavity 104 is not used in an optimal manner in current packaging substrate architectures. For example, certain aspects of the disclosure are implemented with a recognition that the regions occupied by the support structure 116 may be re-purposed. Additionally, certain aspects of the disclosure are implemented with a recognition that it may be possible in certain scenarios to reduce the footprint of electronic components (e.g., DTCs) typically disposed in the cavity 104 to make room for additional electronic component architectures. For example, in the context of DTCs, the current depth T1 (e.g., typically less than about 780 micrometers in a cavity having a depth of greater than 780 micrometers) of existing DTC structures may be reduced to a depth of T3 while still maintaining the function and integrity of the capacitors 108 thereby leaving the volume of the cavity 104 associated with the depth T4 available for additional electronic components. Certain aspects of the disclosure are further implemented with a recognition that the support structure 116 need not be present within the cavity 104 in certain scenarios thereby providing even further room for additional electronic components.

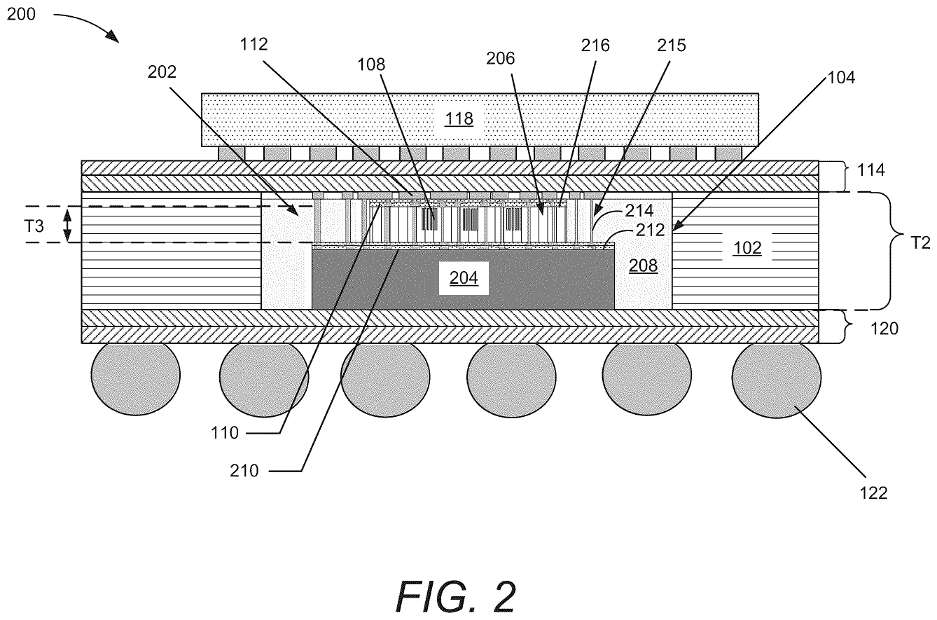

FIG. 2 is a cross-sectional view of an example substrate 200 having stacked electronic components disposed in the cavity of a core, according to aspects of the disclosure. For purposes of simplicity, certain reference numbers used in FIG. 1 have also been used to designate similar elements in FIG. 2.

In accordance with aspects of the disclosure, similar to substrate 100, the example substrate 200 shown in FIG. 2 includes a core 102 having a cavity 104. Likewise, the example substrate 200 includes a set of one or more patterned metallization layers 114 disposed at an upper portion of the core 102. Unlike the example shown in FIG. 1, the example substrate 200 includes a stacked electronic component structure 202 disposed in the cavity 104. In this example, the stacked electronic component structure 202 includes a first electronic component 204 and a second electronic component 206 that at least partially overlies the first electronic component. The first electronic component 204 and second electronic component 206 may be at least partially surrounded by a dielectric material 208. In an aspect, the dielectric material 208 embeds and secures the first electronic component 204 and the second electronic component 206 with one another in the cavity 104.

In an aspect, the first electronic component 204 may include a set of one or more patterned metallization layers 210 at an upper surface 212. A set of via structures 215 electrically connect the first electronic component 204 with the set of patterned metallization layers 114 at the upper portion of the core 102. In an aspect, electrical connections provided by the via structures 215 may include through substrate vias (TSVs) 214, conductive portions of the patterned metallization layers 210, conductive portions of the patterned metallization layers 110, and the metal terminals 112. In an aspect, some of the TSVs 214 may extend through the dielectric material 208 while other TSVs 214 extend through the second electronic component 206.

The second electronic component 206 of the example substrate 200 may include an upper surface 216 having the patterned metallization layers 210. In an aspect, the patterned metallization layers 210 electrically connect the second electronic component 206 with the metallization layers 114 through the metal terminals 112.

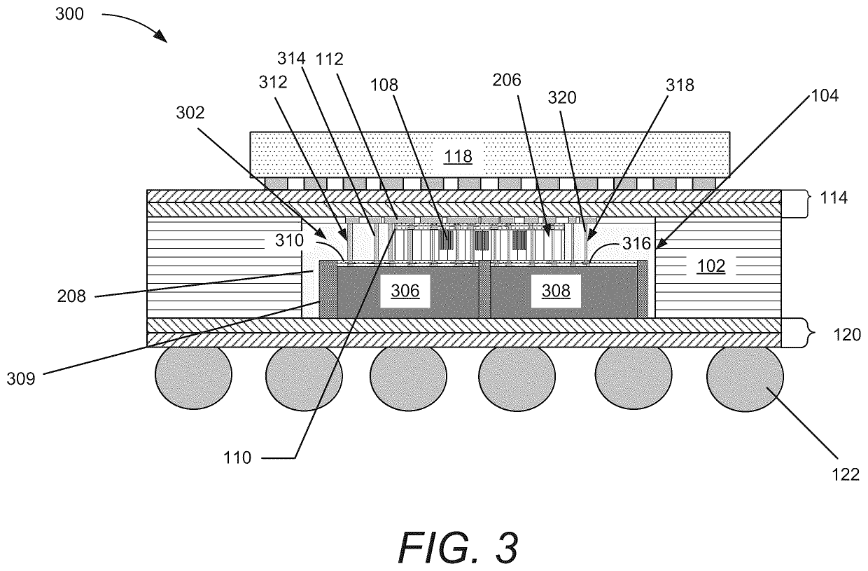

FIG. 3 is a cross-sectional view of an example substrate 300 having stacked electronic components disposed in the cavity of a core, according to aspects of the disclosure. For purposes of simplicity, certain reference numbers used in FIGS. 1 and 2 have also been used to designate similar elements in FIG. 3.

In accordance with aspects of the disclosure, similar to substrate 200, the example substrate 300 shown in FIG. 3 includes a core 102 having a cavity 104. Likewise, the example substrate 300 includes a set of one or more patterned metallization layers 114 disposed at an upper portion of the core 102. Like the example shown in FIG. 2, the example substrate 300 includes a stacked electronic component structure 302 disposed in the cavity 104. In this example, however, the stacked electronic component structure 302 is different than the stacked electronic component structure 202 of FIG. 2. Here, the second electronic component 206 overlies a pair of side-by-side electronic components 306 and 308. In an aspect, the side-by-side electronic components 306 and 308 are at least partially surrounded by a common support material 309 (e.g., molding material). In an aspect, the common support material 309 secures the side-by-side electronic components 306 and 308 in fixed relationship with one another. Here, the electronic components 204, 306, and 308 may be at least partially surrounded by the dielectric material 208. In an aspect, the dielectric material 208 embeds and secures the electronic components 204, 306, and 308 within the cavity 104.

In an aspect, the electronic component 306 may include a set of one or more patterned metallization layers 310 at its upper surface. A set of via structures 312 electrically connect the electronic component 306 with the set of patterned metallization layers 114 at the upper portion of the core 102. In an aspect, the electrical connections provided by the via structures 312 may include through substrate vias (TSVs) 314, conductive portions of the patterned metallization layers 310, conductive portions of the patterned metallization layers 110, and the metal terminals 112. In an aspect, some of the TSVs 314 extend through the dielectric material 208 while other TSVs 314 extend through the electronic component 206.

In an aspect, the electronic component 308 may include a set of one or more patterned metallization layers 316 at its upper surface. A set of via structures 318 electrically connects the electronic component 306 with the set of patterned metallization layers 114 at the upper portion of the core 102. In an aspect, the electrical connections provided by the via structures 318 may include through substrate vias (TSVs) 320, conductive portions of the patterned metallization layers 316, conductive portions of the patterned metallization layers 110, and the metal terminals 112. In an aspect, some of the TSVs 320 extend through the dielectric material 208 while other TSVs 320 extend through the electronic component 206.

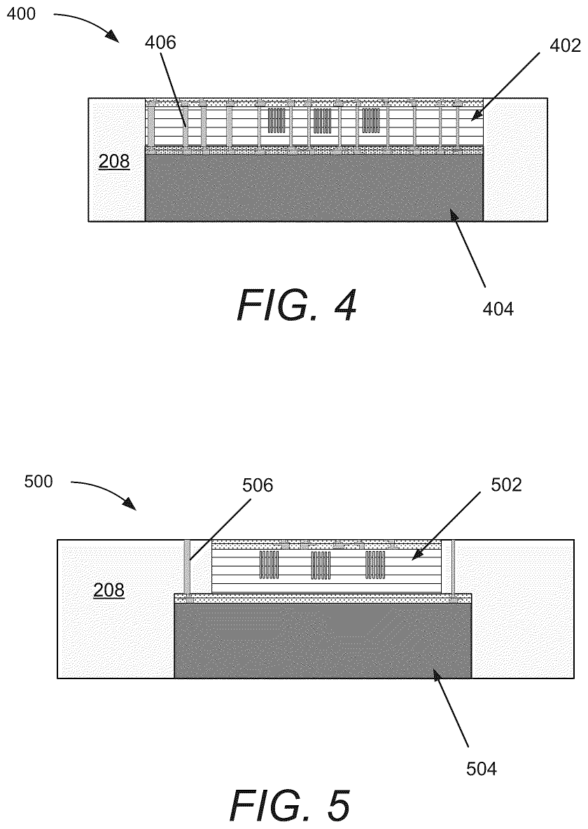

FIG. 4 through FIG. 7 illustrate various stacked electronic component structures, according to aspects of the disclosure. In an aspect, each of the various stacked electronic component structures includes a DTC component that overlies one or more different electronic components in different fusion solution (e.g., the stacking of different types of electronic components) scenarios. However, it will be recognized, in view of the teachings of the present disclosure, that the overlying electronic component may be an electronic component other than a DTC component.

FIG. 4 illustrates an example stacked electronic component structure 400 having a DTC 402 over an electronic component 404 other than a DTC component, according to aspects of the disclosure. In an aspect, the electronic component 404 has a width that is coextensive with the with the width of the DTC 402 and, as such, all of the TSVs 406 extend through the DTC 402.

In an example scenario, the electronic component 404 may be an input/output hub (I/O hub). In an aspect, the I/O hub may be a central component or subsystem that manages input and output operations between the various components of the system. In an aspect, the I/O hub may serve as an interface between processing units (such as a CPU, GPU, memory modules, etc.) and external peripherals or devices. The I/O hub may operate to facilitate communication of data, control signals, and/or power distribution between such internal and external components.

In an example scenario, the electronic component 404 may be a skew matching block. The skew matching block may be a component used to manage or mitigate timing skews in electronic signal paths. For example, in high-speed electronic systems, such as those found in computers, telecommunications equipment, and other digital devices, the timing of signals may be important for proper operation. Signals traveling through different paths can arrive at their destination at slightly different times due to variations in path lengths, material properties, and other factors. This difference in arrival times as skew. A skew matching block may be designed to such timing issues by adjusting the signal paths so that all signals arrive at their destination simultaneously or within a permissible timing window. This can be achieved through various means, such as adding delay lines, using phase-locked loops (PLLs), or employing other circuit techniques to equalize the path lengths or dynamically adjust the timing of signals.

In an aspect, the electronic component 404 may be Serializer/Deserializer (SerDes). In an aspect, such a SerDes may include one or both portions of a pair of functional blocks used in high-speed communications to compensate for limited input/output (I/O) bandwidth by efficiently converting data between serial data and parallel interfaces in each direction.

In an aspect, the electronic component 404 may be an I/O untangling block. In an aspect, the I/O untangling block may facilitate managing, routing, or organizing I/O connections more efficiently. This could involve hardware or software solutions that optimize the layout of connections to minimize cross-talk, electromagnetic interference, or physical constraints within the substrate/package.

FIG. 5 illustrates another example stacked electronic component structure 500 having a DTC 502 over an electronic component 504 other than a DTC component, according to aspects of the disclosure. In an aspect, the electronic component 504 may be a passive circuit element, such as a bulk inductor. In an aspect, such a bulk inductor may be in the inductor that is capable of managing significant power levels for applications like direct-current to direct-current (DC-DC) converters, power management modules, or electromagnetic interference (EMI) filtering. In FIG. 5, the DTC has a width that is less than the width of the electronic component 504. As such, at least some of the TSVs 506 may be routed through the dielectric material 208.

FIG. 6 illustrates another example stacked electronic component structure 600 having a DTC 602 over an electronic component 604 other than a DTC component, according to aspects of the disclosure. In an aspect, the electronic component 604 may be an I/O hub, a SerDes component, a skew matching block, and untangling block, or a combination thereof. In an aspect, the signals 606 associated with the electronic component may be routed through the DTC 602, the dielectric material 208, or a combination thereof.

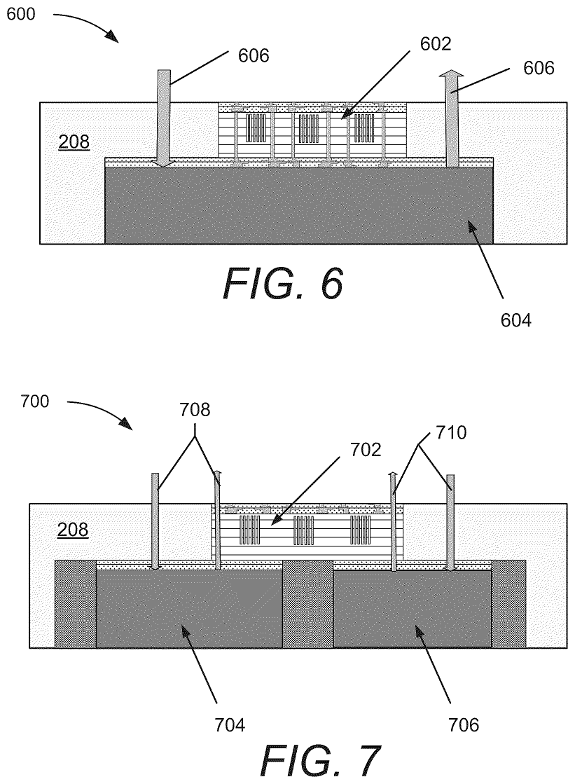

FIG. 7 illustrates another example stacked electronic component structure 700 having a DTC 702 over side-by-side electronic components 704, 706 other than a DTC component, according to aspects of the disclosure. In an aspect, the side-by-side electronic components 704, 706 may include an I/O hub, a SerDes component, a skew matching block, and untangling block, or a combination thereof. In an aspect, the signals 708 associated with the electronic component 704 may be routed through the DTC 702, the dielectric material 208, or a combination thereof. In an aspect, the signals 710 associated with the electronic component 706 may be routed through the DTC 702, the dielectric material 208, or a combination thereof.

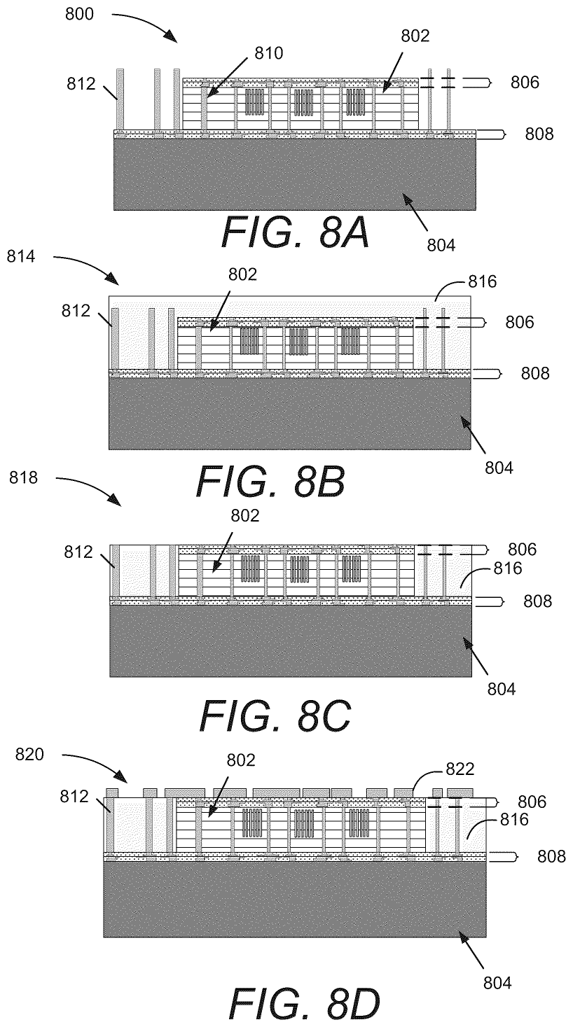

FIG. 8A through FIG. 8D depict exemplary operations that may be used to fabricate a stacked electronic component, according to aspects of the disclosure. In FIG. 8A, the stacked electronic components are shown in an intermediate state 800 in which the electronic component 802 (e.g., DTC) is connected to the electronic component 804. In an aspect, the electronic component 802 may fabricated with the patterned metallization layer 806 in a prior fabrication operation. Similarly, the electronic component 804 may fabricated with the patterned metallization layer 808 in prior fabrication operations. Likewise, the electronic component 802 may be fabricated with the via structures 810 in prior fabrication operations. In FIG. 8A, one or more TSVs 812 are electrically connected with corresponding portions of the patterned metallization layer 808. In an aspect, the TSVs 812 may be attached to the corresponding portions of the patterned metallization layer 808 in a TSV bonding operation.

In FIG. 8B, the stacked electronic components are shown in an intermediate state 814 in which a dielectric material 816 (e.g., molding material) has been deposited over electronic component 802, exposed portions of the patterned metallization layers 806 and 808, and the TSVs 812. In an aspect, the dielectric material 816 may be deposited in a molding fabrication operation.

In FIG. 8C, the stacked electronic components are shown in an intermediate state 818 in which an upper portion of the dielectric material 816 has been removed to expose electrically conductive portions of the patterned metallization layers 806 and 808, and the TSVs 812. In an aspect, the upper portion of the dielectric material 816 may be removed in a chemical mechanical polishing (CMP) operation.

In FIG. 8D, the stacked electronic components are shown in a final state 820 in which metal contacts 822 have been formed for electrical connection with the electrically conductive portions of the patterned metallization layers 806 and 808, and the TSVs 812. In an aspect, the metal contacts 822 may be formed in a standard metal bump fabrication operation (e.g., physical vapor deposition (PVD), chemical vapor deposition (CVD), electroplating, etc.). In an aspect, the final state 820 of the stacked electronic components may be inserted and secured within a cavity of a core for connection with patterned metallization layers disposed over the upper and lower surfaces of the core.

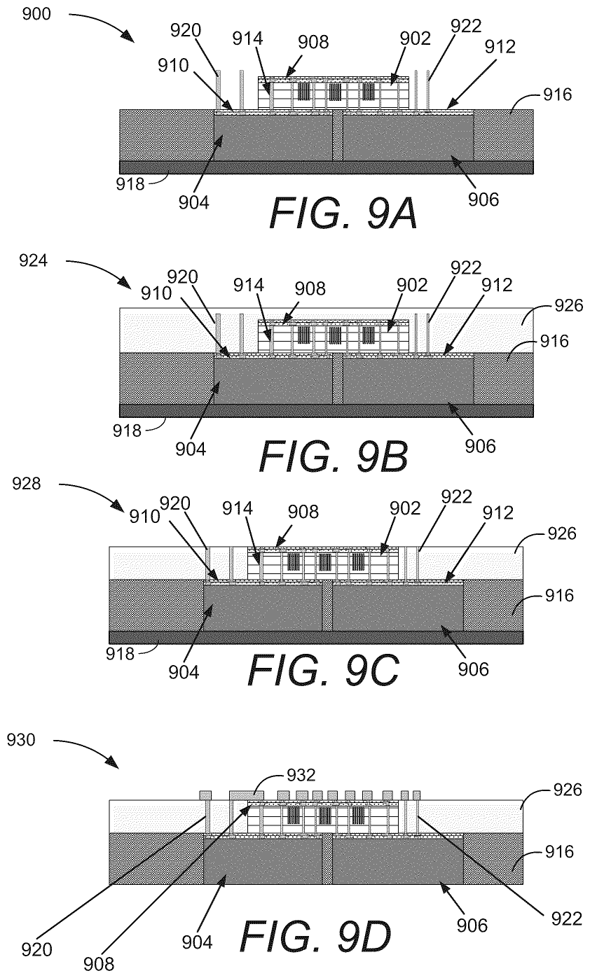

FIG. 9A through FIG. 9D depict exemplary operations that may be used to fabricate a stacked electronic component, according to aspects of the disclosure. In FIG. 9A, the stacked electronic components are shown in an intermediate state 900 in which the electronic component 902 (e.g., DTC) is connected to a pair of side-by-side the electronic components 904 and 906. In an aspect, the electronic component 902 may fabricated with the patterned metallization layer 908 in a prior fabrication operation. Similarly, the side-by-side electronic components 904 and 906 may fabricated with the patterned metallization layers 910 and 912 in prior fabrication operations. Likewise, the electronic component 902 may be fabricated with the respective via structures 914 in prior fabrication operations. For the purposes of the fabrication operations shown in FIG. 9A through FIG. 9, the side-by-side electronic components 904 and 906 may be embedded in a common support material 916 and secured to a carrier 918 in prior fabrication operations. In FIG. 9A, one or more TSVs 920 and 922 are electrically connected with corresponding portions of the patterned metallization layers 910 and 912. In an aspect, the TSVs 920 and 922 may be attached to the corresponding portions of the patterned metallization layers 910 and 912 in a TSV bonding operation.

In FIG. 9B, the stacked electronic components are shown in an intermediate state 924 in which a dielectric material 926 (e.g., molding material) has been deposited over electronic component 902, the side-by-side electronic components 904 and 906, exposed portions of the patterned metallization layers 908, 910, and 912, and the TSVs 920 and 922. In an aspect, the dielectric material 96 may be deposited in a molding fabrication operation.

In FIG. 9C, the stacked electronic components are shown in an intermediate state 928 in which an upper portion of the dielectric material 926 has been removed to expose electrically conductive portions of the patterned metallization layers 908, 910, and 912, and the TSVs 920 and 922. In an aspect, the upper portion of the dielectric material 926 may be removed in a chemical mechanical polishing (CMP) operation.

In FIG. 9D, the stacked electronic components are shown in a final state in 930 in which metal contacts 932 have been formed for electrical connection with the electrically conductive portions of the patterned metallization layer 908, and the TSVs 920 and 922. In an aspect, the metal contacts 932 may be formed in a standard metal bump fabrication operation (e.g., physical vapor deposition (PVD), chemical vapor deposition (CVD), electroplating, etc.). In an aspect, the final state 930 of the stacked electronic components may be inserted and secured in a cavity of a core for connection with patterned metallization layers disposed over the upper and lower surfaces of the core.

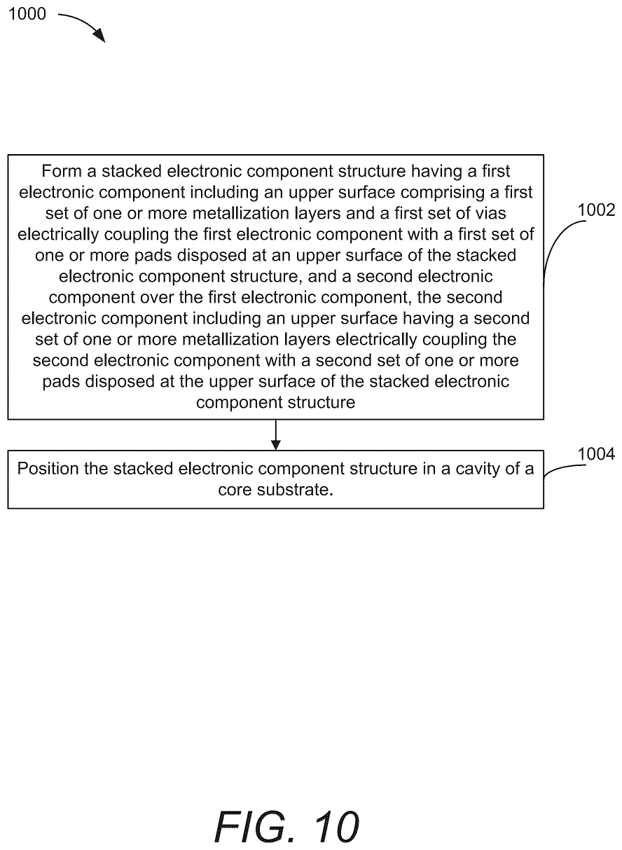

FIG. 10 is a flowchart showing an example method 1000 for fabricating a substrate, according to aspects of the disclosure. At operation 1002, a stacked electronic component structure is formed comprising a first electronic component including an upper surface having a first set of one or more metallization layers and a first set of vias electrically coupling the first electronic component with a first set of one or more pads disposed at an upper surface of the stacked electronic component structure, and a second electronic component over the first electronic component, the second electronic component including an upper surface having a second set of one or more metallization layers electrically coupling the second electronic component with a second set of one or more pads disposed at the upper surface of the stacked electronic component structure. At operation 1004, the stacked electronic component structure is positioned in a cavity of a core substrate.

A technical advantage of the method 1000 is that the method may be used to form a substrate in a manner that facilitates optimal use of a cavity in a core. In an aspect, the resulting method may provide a substrate that is fabricated with a stacked electronic component structure stacked to meet the increasing demands of electronic packaging density requirements.

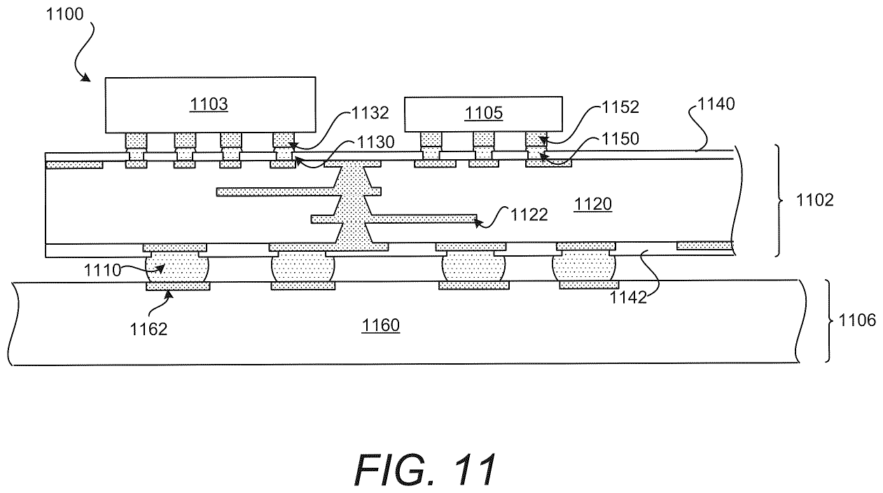

FIG. 11 illustrates a profile view of a package 1100 that includes a surface mount substrate 1102, an integrated device 1103, and an integrated device 1105 (e.g., a substrate having embedded stacked electronic components and a core), according to aspects of the disclosure. The package 1100 may be coupled to a printed circuit board (PCB) 1106 through a plurality of solder interconnects 1110. The PCB 1106 may include at least one board dielectric layer 1160 and a plurality of board interconnects 1162.

The surface mount substrate 1102 includes at least one dielectric layer 1120 (e.g., substrate dielectric layer), a plurality of interconnects 1122 (e.g., substrate interconnects), a solder resist layer 1140 and a solder resist layer 1142. The integrated device 1103 may be coupled to the surface mount substrate 1102 through a plurality of solder interconnects 1130. The integrated device 1103 may be coupled to the surface mount substrate 1102 through a plurality of pillar interconnects 1132 and the plurality of solder interconnects 1130. The integrated device 1105 may be coupled to the surface mount substrate 1102 through a plurality of solder interconnects 1150. The integrated device 1105 may be coupled to the surface mount substrate 1102 through a plurality of pillar interconnects 1152 and the plurality of solder interconnects 1150.

The package (e.g., 1100) may be implemented in a radio frequency (RF) package. The RF package may be a radio frequency front end (RFFE) package. A package (e.g., 1100) may be configured to provide Wireless Fidelity (WiFi) communication and/or cellular communication (e.g., 2G, 3G, 4G, 5G). The package (e.g., 1100) may be configured to support Global System for Mobile (GSM) Communications, Universal Mobile Telecommunications System (UMTS), and/or Long-Term Evolution (LTE). The package (e.g., 1100) may be configured to transmit and receive signals having different frequencies and/or communication protocols.

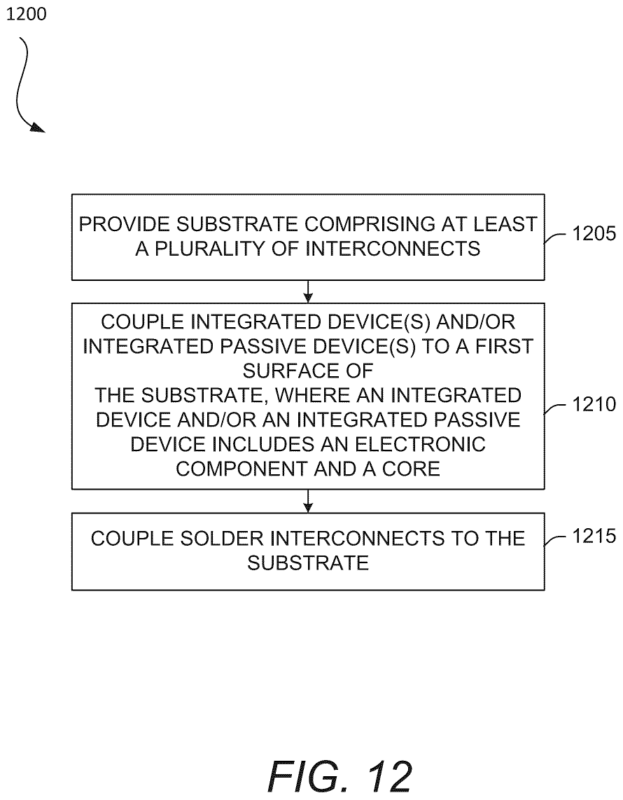

FIG. 12 illustrates an example method 1200 for providing or fabricating a package that includes an integrated device comprising a substrate having an electronic component on a core, according to aspects of the disclosure. In some implementations, the method 1200 of FIG. 12 may be used to provide or fabricate the package 1100 of FIG. 11 described in the disclosure. However, the method 1200 may be used to provide or fabricate any of the packages described in the disclosure.

It should be noted that the method of FIG. 12 may combine one or more processes in order to simplify and/or clarify the method for providing or fabricating a package that includes an integrated device comprising a magnetic layer and/or an integrated passive device comprising a magnetic layer. In some implementations, the order of the processes may be changed or modified.

The method provides (at 1205) a surface mount substrate (e.g., 1102). The surface mount substrate 1102 may be provided by a supplier or fabricated. The surface mount substrate 1102 includes at least one dielectric layer 1120 and a plurality of interconnects 1122. The surface mount substrate 1102 may include an embedded trace substrate (ETS). In some implementations, the at least one dielectric layer 1120 may include prepreg layers.

The method couples (at 1210) at least one integrated device (e.g., 1103) to the first surface of the substrate (e.g., 1102). For example, the integrated device 1103 may be coupled to the surface mount substrate 1102 through the plurality of pillar interconnects 1132 and the plurality of solder interconnects 1130. The plurality of pillar interconnects 1132 may be optional. The plurality of solder interconnects 1130 are coupled to the plurality of interconnects 1122. A solder reflow process may be used to couple the integrated device 1103 to the plurality of interconnects through the plurality of solder interconnects 1130.

The method also couples (at 1210) at least one integrated passive device (e.g., 1105) to the first surface of the substrate (e.g., 1102). For example, the integrated device 1105 may be coupled to the surface mount substrate 1102 through the plurality of pillar interconnects 1152 and the plurality of solder interconnects 1150. The plurality of pillar interconnects 1152 may be optional. The plurality of solder interconnects 1150 are coupled to the plurality of interconnects 1122. A solder reflow process may be used to couple the integrated device 1105 to the plurality of interconnects through the plurality of solder interconnects 1150.

The method couples (at 1215) a plurality of solder interconnects (e.g., 1110) to the second surface of the substrate (e.g., 1102). A solder reflow process may be used to couple the plurality of solder interconnects 1110 to the substrate.

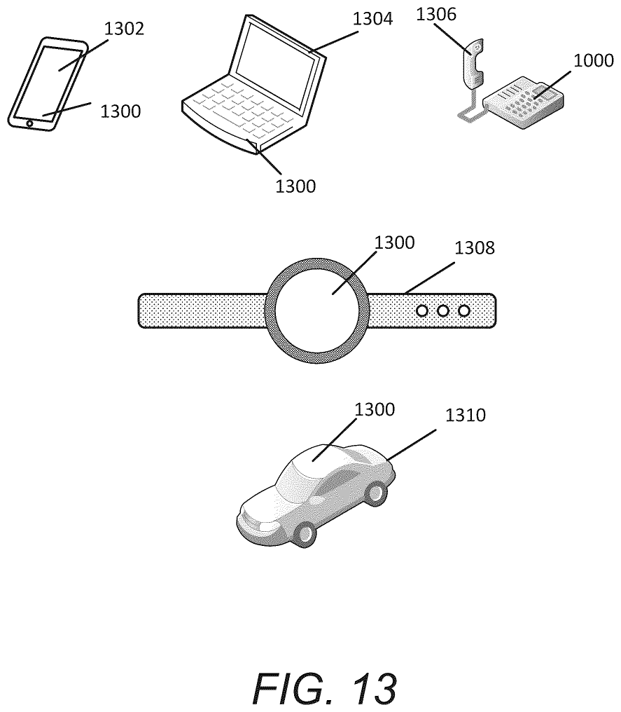

FIG. 13 illustrates various electronic devices that may be integrated with any of the aforementioned devices, integrated devices, integrated circuit (IC) packages, integrated package-on-package (PoP), System in Package (SiP), or System on Chip (SoC). For example, a mobile phone device 1302, a laptop computer device 1304, a fixed location terminal device 1306, a wearable device 1308, or automotive vehicle 1310 may include a device 1300 as described herein. The device 1300 may be, for example, any of the devices and/or integrated circuit (IC) packages described herein. The devices 1302, 1304, 1306 and 1308 and the vehicle 1310 illustrated in FIG. 13 are merely exemplary. Other electronic devices may also feature the device 1300 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

Implementation examples are described in the following numbered aspects:

Aspect 1. A substrate, comprising: a core having a cavity; a first set of one or more metallization layers disposed at an upper portion of the core; and a stacked electronic component structure disposed in the cavity, wherein the stacked electronic component structure comprises a first electronic component including an upper surface having a second set of one or more metallization layers and a first set of via structures electrically coupling the first electronic component with the first set of one or more metallization layers, and a second electronic component over the first electronic component, the second electronic component including an upper surface having a third set of one or more metallization layers electrically coupling the second electronic component with the first set of one or more metallization layers.

Aspect 2. The substrate of aspect 1, wherein: the second electronic component comprises a deep trench capacitor (DTC).

Aspect 3. The substrate of any of aspects 1 to 2, wherein: the first electronic component comprises an input/output (I/O) hub.

Aspect 4. The substrate of any of aspects 1 to 3, wherein: the first electronic component comprises a skew-matching block.

Aspect 5. The substrate of any of aspects 1 to 4, wherein: the first electronic component comprises a bulk inductor.

Aspect 6. The substrate of any of aspects 1 to 5, wherein: the first electronic component comprises an input/output (I/O) untangling block.

Aspect 7. The substrate of any of aspects 1 to 6, wherein the stacked electronic component structure further comprises: a third electronic component disposed alongside the first electronic component, the third electronic component having an upper surface having a third set of one or more metallization layers and a second set of via structures electrically coupling the third electronic component with the first set of one or more metallization layers.

Aspect 8. The substrate of aspect 7, wherein: the first electronic component and the third electronic component are disposed alongside one another in a common support material.

Aspect 9. The substrate of any of aspects 1 to 8, wherein: the core has a thickness that is greater than about 780 micrometers.

Aspect 10. An electronic device, comprising: a substrate comprising a core substrate including a core having a cavity; a first set of one or more metallization layers disposed at an upper portion of the cavity; and a stacked electronic component structure disposed in the cavity, wherein the stacked electronic component structure comprises a first electronic component including an upper surface having a second set of one or more metallization layers and a first set of vias electrically coupling the first electronic component with the first set of one or more metallization layers, and a second electronic component over the first electronic component, the second electronic component including an upper surface having a third set of one or more metallization layers electrically coupling the second electronic component with the first set of one or more metallization layers.

Aspect 11. The substrate of aspect 10, wherein: the second electronic component comprises a deep trench capacitor (DTC).

Aspect 12. The substrate of any of aspects 10 to 11, wherein: the first electronic component comprises an input/output (I/O) hub.

Aspect 13. The substrate of any of aspects 10 to 12, wherein: the first electronic component comprises a skew-matching block.

Aspect 14. The substrate of any of aspects 10 to 13, wherein: the first electronic component comprises a bulk inductor.

Aspect 15. The substrate of any of aspects 10 to 14, wherein: the first electronic component comprises an input/output (I/O) untangling block.

Aspect 16. The substrate of any of aspects 10 to 15, wherein the stacked electronic component structure further comprises: a third electronic component disposed alongside the first electronic component, the third electronic component having an upper surface having a third set of one or more metallization layers and a second set of vias electrically coupling the third electronic component with the first set of one or more metallization layers.

Aspect 17. The substrate of aspect 16, wherein: the first electronic component and the third electronic component are disposed alongside one another in a common support material.

Aspect 18. The substrate of any of aspects 10 to 17, wherein: the core has a thickness that is greater than about 780 micrometers.

Aspect 19. The electronic device of any of aspects 10 to 18, wherein the electronic device comprises at least one of: a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

Aspect 20. A method of forming a substrate, comprising: forming a stacked electronic component structure comprising a first electronic component including an upper surface having a first set of one or more metallization layers and a first set of vias electrically coupling the first electronic component with a first set of one or more pads disposed at an upper surface of the stacked electronic component structure, and a second electronic component over the first electronic component, the second electronic component including an upper surface having a second set of one or more metallization layers electrically coupling the second electronic component with a second set of one or more pads disposed at the upper surface of the stacked electronic component structure; and positioning the stacked electronic component structure in a cavity of a core substrate.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

It is noted that the figures in the disclosure may represent actual representations and/or conceptual representations of various parts, components, objects, devices, packages, integrated devices, integrated circuits, and/or transistors. In some instances, the figures may not be to scale. In some instances, for the purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’,” or “approximately value X,” as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an underbump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metallization layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the detailed description above, it can be seen that different features are grouped together in examples. This manner of disclosure should not be understood as an intention that the example aspects have more features than are explicitly mentioned in each aspect. Rather, the various aspects of the disclosure may include fewer than all features of an individual example aspect disclosed. Therefore, the following aspects should hereby be deemed to be incorporated in the description, wherein each aspect by itself can stand as a separate example. Although each dependent aspect can refer to the aspects of a specific combination with one of the other aspects, the aspect(s) of that dependent aspect are not limited to the specific combination. It will be appreciated that other example aspects can also include a combination of the dependent aspect(s) with the subject matter of any other dependent aspect or independent aspect or a combination of any feature with other dependent and independent aspects. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of an aspect can be included in any other independent aspect, even if the aspect is not directly dependent on the independent aspect.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A substrate, comprising:
a core having a cavity;
a first set of one or more metallization layers disposed at an upper portion of the core; and
a stacked electronic component structure disposed in the cavity, wherein the stacked electronic component structure comprises:
a first electronic component including an upper surface having a second set of one or more metallization layers and a first set of via structures electrically coupling the first electronic component with the first set of one or more metallization layers, and
a second electronic component over the first electronic component, the second electronic component including an upper surface having a third set of one or more metallization layers electrically coupling the second electronic component with the first set of one or more metallization layers.

2. The substrate of claim 1, wherein:
the second electronic component comprises a deep trench capacitor (DTC).

3. The substrate of claim 1, wherein:
the first electronic component comprises an input/output (I/O) hub.

4. The substrate of claim 1, wherein:
the first electronic component comprises a skew-matching block.

5. The substrate of claim 1, wherein:
the first electronic component comprises a bulk inductor.

6. The substrate of claim 1, wherein:
the first electronic component comprises an input/output (I/O) untangling block.

7. The substrate of claim 1, wherein the stacked electronic component structure further comprises:
a third electronic component disposed alongside the first electronic component, the third electronic component having an upper surface having a third set of one or more metallization layers and a second set of via structures electrically coupling the third electronic component with the first set of one or more metallization layers.

8. The substrate of claim 7, wherein:
the first electronic component and the third electronic component are disposed alongside one another in a common support material.

9. The substrate of claim 1, wherein:
the core has a thickness that is greater than about 780 micrometers.

10. An electronic device, comprising:
a substrate comprising:
a core substrate including a core having a cavity;
a first set of one or more metallization layers disposed at an upper portion of the cavity; and
a stacked electronic component structure disposed in the cavity, wherein the stacked electronic component structure comprises:
a first electronic component including an upper surface having a second set of one or more metallization layers and a first set of vias electrically coupling the first electronic component with the first set of one or more metallization layers, and
a second electronic component over the first electronic component, the second electronic component including an upper surface having a third set of one or more metallization layers electrically coupling the second electronic component with the first set of one or more metallization layers.

11. The substrate of claim 10, wherein:
the second electronic component comprises a deep trench capacitor (DTC).

12. The substrate of claim 10, wherein:
the first electronic component comprises an input/output (I/O) hub.

13. The substrate of claim 10, wherein:
the first electronic component comprises a skew-matching block.

14. The substrate of claim 10, wherein:
the first electronic component comprises a bulk inductor.

15. The substrate of claim 10, wherein:
the first electronic component comprises an input/output (I/O) untangling block.

16. The substrate of claim 10, wherein the stacked electronic component structure further comprises:
a third electronic component disposed alongside the first electronic component, the third electronic component having an upper surface having a third set of one or more metallization layers and a second set of vias electrically coupling the third electronic component with the first set of one or more metallization layers.

17. The substrate of claim 16, wherein:
the first electronic component and the third electronic component are disposed alongside one another in a common support material.

18. The substrate of claim 10, wherein:
the core has a thickness that is greater than about 780 micrometers.

19. The electronic device of claim 10, wherein the electronic device comprises at least one of:
a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

20. A method of forming a substrate, comprising:
forming a stacked electronic component structure comprising:
a first electronic component including an upper surface having a first set of one or more metallization layers and a first set of vias electrically coupling the first electronic component with a first set of one or more pads disposed at an upper surface of the stacked electronic component structure, and
a second electronic component over the first electronic component, the second electronic component including an upper surface having a second set of one or more metallization layers electrically coupling the second electronic component with a second set of one or more pads disposed at the upper surface of the stacked electronic component structure; and
positioning the stacked electronic component structure in a cavity of a core substrate.
